(19) United States
(12) Patent Application Publication
(10) Pub. No.: US 2013/0162996 A1
(43) Pub. Date: Jun. 27, 2013

(54) Inspection Method and Apparatus, and Lithographic Apparatus

(71) Applicants: Alexander STRAAIJER, Eindhoven (NL); Arno Jan BLEEKER, Westerhoven (NL)

(72) Inventors: Alexander STRAAIJER, Eindhoven (NL); Arno Jan BLEEKER, Westerhoven (NL)

(73) Assignee: ASML Netherlands B.V., Veldhoven (NL)

(21) Appl. No.: 13/533,110

(22) Filed: Jun. 26, 2012

Related U.S. Application Data
(60) Provisional application No. 61/509,751, filed on Jul. 20, 2011.

(51) Int. Cl. G03F 7/20

(52) U.S. Cl. CPC G03F 7/70633
USPC 356/369

(57) ABSTRACT

An inspection method reflects radiation with a known polarization beam off a periodic structure, such as a grating. The reflected radiation beam is split into first and second orthogonally polarized sub-beams. The phase of the first sub-beams is shifted with respect to the second sub-beam. A first image resultant from the first sub-beam and a second image resultant from the second sub-beam are simultaneously detected. A difference in intensity values is used to derived from the detected first and second images together to determine an overlay error in the periodic structure.

### CROSS REFERENCE TO RELATED APPLICATIONS

This application claims the benefit under 35 U.S.C. §119(e) to U.S. Provisional Patent Application No. 61/509,751, filed Jul. 20, 2011, which is incorporated by reference herein in its entirety.

### FIELD

The present invention relates to methods of inspection usable, for example, in the manufacture of devices by lithographic techniques. In particular it relates to methods of determining an overlay error in the devices.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

In order to monitor the lithographic process, parameters of the patterned substrate are measured. Parameters may include, for example, the overlay error between successive layers formed in or on the patterned substrate and critical linewidth of developed photosensitive resist. This measurement may be performed on a product substrate and/or on a dedicated metrology target. There are various techniques for making measurements of the microscopic structures formed in lithographic processes, including the use of scanning electron microscopes and various specialized tools. A fast and non-invasive form of specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Two main types of scatterometer are known. Spectroscopic scatterometers direct a broadband radiation beam onto the substrate and measure the spectrum (intensity as a function of wavelength) of the radiation scattered into a particular narrow angular range. Angularly resolved scatterometers use a monochromatic radiation beam and measure the intensity of the scattered radiation as a function of angle.

Rather than just measuring the intensity variation within an illumination beam, generally, ellipsometry is the measurement of the state of polarization of scattered light. Ellipsometry measures two parameters: the phase difference (Δ) between two differently polarized beams and an amplitude ratio (tanΨ) of two polarized beams. With these two parameters, any polarization state of a purely polarized beam may be described.

Specifically, if an incident beam has both s and p polarizations, the reflected beam will have reflectance coefficients Rp and Rs. Δ (Delta) is the phase difference between the reflectance coefficients Rp and Rs as given in equation (1) below. The angle between the two polarization directions (or orientations) is Ψ and so the relationship between Ψ and Rp and Rs is as follows in equation (2).

Δ=arg(Rₚ−Rₛ) (1)

tanΨ=Rₚ/Rₛ (2)

### SUMMARY

It is desirable to provide a method and system that alleviates some or all of the above mentioned problems.

According to an aspect of the invention, there is provided an inspection method comprising the steps of providing a radiation beam with a known polarization, reflecting the radiation beam off a periodic structure on a substrate, the periodic structure having been formed by a lithographic process, splitting the reflected radiation beam into first and second orthogonally polarized sub-beams, shifting the phase of the first sub-beams with respect to the second sub-beam, simultaneously detecting a first image resultant from the first sub-beam and a second image resultant from the second sub-beam, using a difference in intensity values derived from the detected first and second images together to determine an overlay error in the periodic structure.

According to second and third aspects of the present invention, there are provided inspection and lithography apparatuses for carrying out the methods disclosed herein.

According to a fourth and fifth aspects of the present invention, there are provided computer readable media comprising instruction code for controlling the inspection and lithography apparatuses to carry out the methods disclosed herein.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 depicts a lithographic apparatus.

FIG. 2 depicts a lithographic cell or cluster.

FIG. 3 depicts a first scatterometer.

FIG. 4 depicts a second scatterometer.

FIG. 5 depicts a first ellipsometry arrangement.

FIGS. 6a and 6b illustrate the problem of asymmetry in the bottom layer.

FIG. 7 is a graph showing the measured overlay against the degree of floortilt in a trench etched in the bottom layer.

FIG. 8 is a graph showing the measured overlay against the degree of SWA asymmetry in a trench etched in the bottom layer.

FIG. 9 is a graph showing the measured overlay against the degree of floortilt in a trench etched in the bottom layer.

FIG. 10 is a graph showing the measured overlay against the degree of SWA asymmetry in a trench etched in the bottom layer.

FIGS. 11a, 11b and 11c depicts a combined ellipsometer/scatterometer illustrating a second ellipsometry arrangement.

FIG. 12 depicts a first operation arrangement of the combined ellipsometer/scatterometer of FIG. 11.

FIG. 13 depicts a second operation arrangement of the combined ellipsometer/scatterometer of FIG. 11.

FIG. 14 depicts a third operation arrangement of the combined ellipsometer/scatterometer of FIG. 11.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present invention may be implemented.

All exemplary reference and documents noted below are hereby incorporated by reference herein in their entireties.

Background on ellipsometric delta and psi can be found in many textbooks, for example “Ellipsometry and Polarized Light” by Azzam & Bashara. The extension of ellipsometry techniques in Scatterometry have already been discussed in patent applications such as WO2009/115342 (adjustable retarder) and U.S. patent publication 2009/0168062 (fixed retarder). Both of these documents are incorporated herein by reference. In these proposals a choice of two linearly polarized input beams TM and TE, with respect to the instrument's x-axis, has been chosen. This light is projected with the high NA objective lens onto the grating under test where multi azimuths and multi angles of incidence are created. After reflection the light near the pupil x-axis and y-axis remain predominantly linearly polarized. However on the pupil plane diagonals, at 45-degrees, the beam becomes elliptical mainly because of ellipsometric Delta by reflection but also phase shifts in the objective lens.

Furthermore, U.S. Pat. No. 7,369,224 discloses a surface inspection apparatus comprising an illumination means for illuminating a pattern formed through a predetermined pattern forming process containing a process of exposure of a resist layer formed on a substrate having a periodicity with a linearly polarized light, a setting means for setting a direction of the substrate such that a plane of vibration of the linear polarization and a direction of repetition of the pattern are obliquely to each other, an extraction means for extracting a polarization component having a plane of vibration perpendicular to that of the linear polarization out of specularly reflected light from the pattern, and an image forming means for forming an image of the surface of the substrate based on the extracted light. A pattern forming condition in the pattern forming process is specified based on the light intensity of the image of the surface of the substrate formed by the image forming means. However, such a device has a fixed angle for both azimuth and incidence, the chosen angles being essential for the operation of the device. As a consequence it needs to use an effective medium approach as if the grating as a sort of thin layer for the calculation. It can then make use of the difference of two refractive indices Nx-Ny. These represent weaknesses in this prior art device.

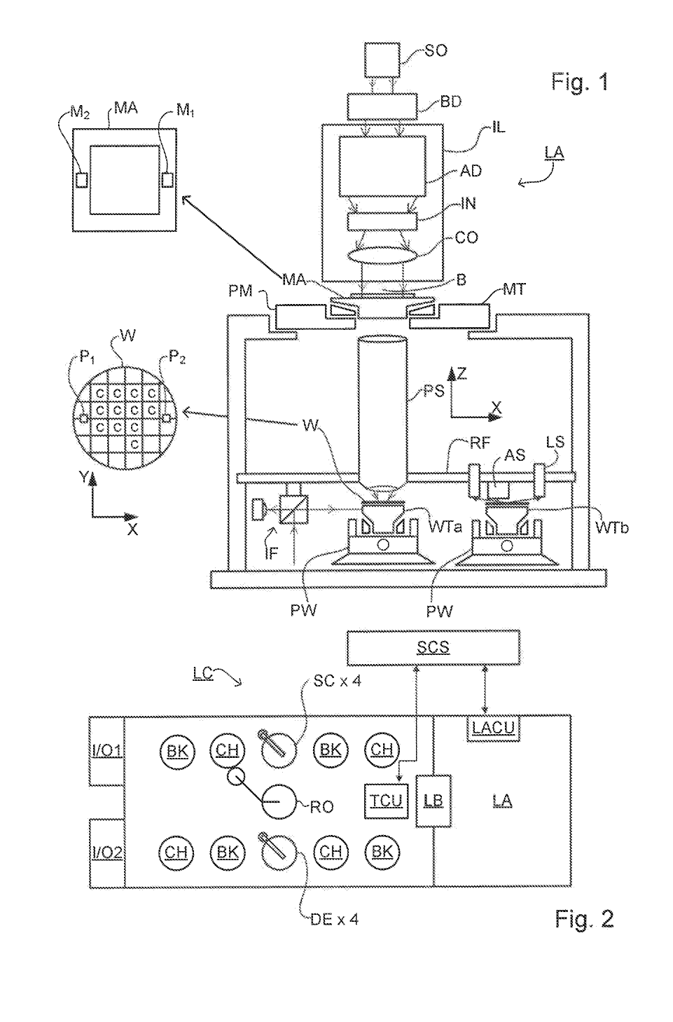

FIG. 1 schematically depicts a lithographic apparatus. The apparatus comprises—an illumination system (illuminator) IL configured to condition a radiation beam B (e.g., UV radiation or DUV radiation), a support structure (e.g., a mask table) MT constructed to support a patterning device (e.g., a mask) MA and connected to a first positioner PM configured to accurately position the patterning device in accordance with certain parameters, a substrate table (e.g., a wafer table) WT constructed to hold a substrate (e.g., a resist-coated wafer) W and connected to a second positioner PW configured to accurately position the substrate in accordance with certain parameters, and a projection system (e.g., a refractive projection lens system) PL configured to project a pattern imparted to the radiation beam B by patterning device MA onto a target portion C (e.g., comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure supports, i.e., bears the weight of, the patterning device. It holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g., employing a transmissive mask). Alternatively, the apparatus may be of a reflective type (e.g., employing a programmable mirror array of a type as referred to above, or employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as a-outer and a-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross-section.

The radiation beam B is incident on the patterning device (e.g., mask MA), which is held on the support structure (e.g., mask table MT), and is patterned by the patterning device. Having traversed the mask MA, the radiation beam B passes through the projection system PL, which focuses the beam onto a target portion C of the substrate W. With the aid of the second positioner PW and position sensor IF (e.g., an interferometric device, linear encoder, 2-D encoder or capacitive sensor), the substrate table WT can be moved accurately, e.g., so as to position different target portions C in the path of the radiation beam B. Similarly, the first positioner PM and another position sensor (which is not explicitly depicted in FIG. 1) can be used to accurately position the mask MA with respect to the path of the radiation beam B, e.g., after mechanical retrieval from a mask library, or during a scan. In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The depicted apparatus could be used in at least one of the following modes:

1. In step mode, the mask table MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the mask table MT and the substrate table WT are scanned synchronously while a pattern imparted to the radiation beam is projected onto a target portion C (i.e., a single dynamic exposure). The velocity and direction of the substrate table WT relative to the mask table MT may be determined by the (de-)magnification and image reversal characteristics of the projection system PL. In scan mode, the maximum size of the exposure field limits the width (in the non-scanning direction) of the target portion in a single dynamic exposure, whereas the length of the scanning motion determines the height (in the scanning direction) of the target portion.

3. In another mode, the mask table MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

As shown in FIG. 2, the lithographic apparatus LA forms part of a lithographic cell LC, also sometimes referred to a lithocell or cluster, which also includes apparatus to perform pre- and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, 1/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

In order that the substrates that are exposed by the lithographic apparatus are exposed correctly and consistently, it is desirable to inspect exposed substrates to measure properties such as overlay errors between subsequent layers, line thicknesses, critical dimensions (CD), etc. If errors are detected, adjustments may be made to exposures of subsequent substrates, especially if the inspection can be done soon and fast enough that other substrates of the same batch are still to be exposed. Also, already exposed substrates may be stripped and reworked—to improve yield—or discarded, thereby avoiding performing exposures on substrates that are known to be faulty. In a case where only some target portions of a substrate are faulty, further exposures can be performed only on those target portions which are good.

An inspection apparatus is used to determine the properties of the substrates, and in particular, how the properties of different substrates or different layers of the same substrate vary from layer to layer. The inspection apparatus may be integrated into the lithographic apparatus LA or the lithocell LC or may be a stand-alone device. To enable most rapid measurements, it is desirable that the inspection apparatus measure properties in the exposed resist layer immediately after the exposure. However, the latent image in the resist has a very low contrast—there is only a very small difference in refractive index between the parts of the resist which have been exposed to radiation and those which have not—and not all inspection apparatus have sufficient sensitivity to make useful measurements of the latent image. Therefore measurements may be taken after the post-exposure bake step (PEB) which is customarily the first step carried out on exposed substrates and increases the contrast between exposed and unexposed parts of the resist. At this stage, the image in the resist may be referred to as semi-latent. It is also possible to make measurements of the developed resist image—at which point either the exposed or unexposed parts of the resist have been removed—or after a pattern transfer step such as etching. The latter possibility limits the possibilities for rework of faulty substrates but may still provide useful information.

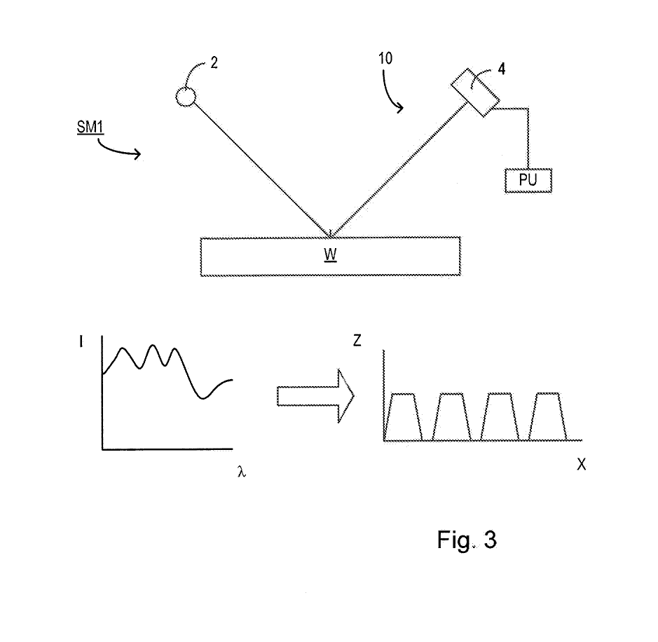

FIG. 3 depicts a scatterometer which may be used in the present invention. It comprises a broadband (white light) radiation projector 2 which projects radiation onto a substrate W. The reflected radiation is passed to a spectrometer detector 4, which measures a spectrum 10 (intensity as a function of wavelength) of the specular reflected radiation. From this data, the structure or profile giving rise to the detected spectrum may be reconstructed by processing unit PU, e.g., by Rigorous Coupled Wave Analysis and non-linear regression or by comparison with a library of simulated spectra as shown at the bottom of FIG. 3. In general, for the reconstruction the general form of the structure is known and some parameters are assumed from knowledge of the process by which the structure was made, leaving only a few parameters of the structure to be determined from the scatterometry data. Such a scatterometer may be configured as a normal-incidence scatterometer or an oblique-incidence scatterometer.

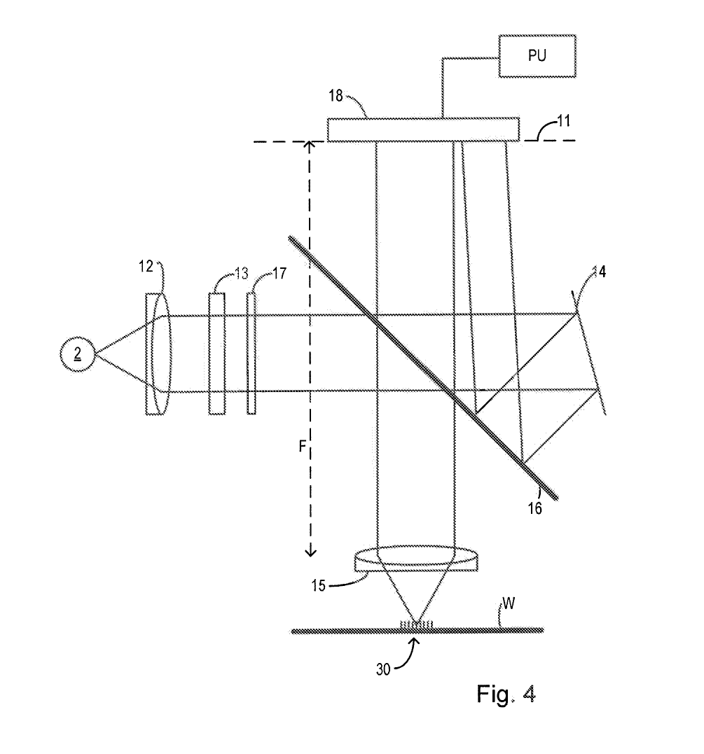

Another scatterometer that may be used with the present invention is shown in FIG. 4. In this device, the radiation emitted by radiation source 2 is collimated using lens system 12 and transmitted through interference filter 13 and polarizer 17, reflected by partially reflected surface 16 and is focused onto substrate W via a microscope objective lens 15, which has a high numerical aperture (NA), preferably at least 0.9 and more preferably at least 0.95. Immersion scatterometers may even have lenses with numerical apertures over 1. The reflected radiation then transmits through partially reflecting surface 16 into a detector 18 in order to have the scatter spectrum detected. The detector may be located in the back-projected pupil plane 11, which is at the focal length of the lens system 15, however the pupil plane may instead be re-imaged with auxiliary optics (not shown) onto the detector. The pupil plane is the plane in which the radial position of radiation defines the angle of incidence and the angular position defines azimuth angle of the radiation. The detector is preferably a two-dimensional detector so that a two-dimensional angular scatter spectrum of a substrate target 30 can be measured. The detector 18 may be, for example, an array of CCD or CMOS sensors, and may use an integration time of, for example, 40 milliseconds per frame.

A reference beam is often used for example to measure the intensity of the incident radiation. To do this, when the radiation beam is incident on the beam splitter 16 part of it is transmitted through the beam splitter as a reference beam towards a reference mirror 14. The reference beam is then projected onto a different part of the same detector 18 or alternatively on to a different detector (not shown).

A set of interference filters 13 is available to select a wavelength of interest in the range of, say, 405-790 nm or even lower, such as 200-300 nm. The interference filter may be tunable rather than comprising a set of different filters. A grating could be used instead of interference filters.

The detector 18 may measure the intensity of scattered light at a single wavelength (or narrow wavelength range), the intensity separately at multiple wavelengths or integrated over a wavelength range. Furthermore, the detector may separately measure the intensity of transverse magnetic- and transverse electric-polarized light and/or the phase difference between the transverse magnetic- and transverse electric-polarized light.

Using a broadband light source (i.e., one with a wide range of light frequencies or wavelengths—and therefore of colors) is possible, which gives a large etendue, allowing the mixing of multiple wavelengths. The plurality of wavelengths in the broadband preferably each has a bandwidth of Δλ and a spacing of at least 2 Δλ (i.e., twice the bandwidth). Several “sources” of radiation can be different portions of an extended radiation source which have been split using fiber bundles. In this way, angle resolved scatter spectra can be measured at multiple wavelengths in parallel. A 3-D spectrum (wavelength and two different angles) can be measured, which contains more information than a 2-D spectrum. This allows more information to be measured which increases metrology process robustness. This is described in more detail in EP1,628,164A.

The target 30 on substrate W may be a 1-D grating, which is printed such that after development, the bars are formed of solid resist lines. The target 30 may be a 2-D grating, which is printed such that after development, the grating is formed of solid resist pillars or vias in the resist. The bars, pillars or vias may alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. Accordingly, the scatterometry data of the printed gratings is used to reconstruct the gratings. The parameters of the 1-D grating, such as line widths and shapes, or parameters of the 2-D grating, such as pillar or via widths or lengths or shapes, may be input to the reconstruction process, performed by processing unit PU, from knowledge of the printing step and/or other scatterometry processes.

As described above, the target is on the surface of the substrate. This target will often take the shape of a series of lines in a grating or substantially rectangular structures in a 2-D array. The purpose of rigorous optical diffraction theories in metrology is effectively the calculation of a diffraction spectrum that is reflected from the target. In other words, target shape information is obtained for CD (critical dimension) uniformity and overlay metrology. Overlay metrology is a measuring system in which the overlay of two targets is measured in order to determine whether two layers on a substrate are aligned or not. CD uniformity is simply a measurement of the uniformity of the grating on the spectrum to determine how the exposure system of the lithographic apparatus is functioning. Specifically, CD, or critical dimension, is the width of the object that is “written” on the substrate and is the limit at which a lithographic apparatus is physically able to write on a substrate.

Ellipsometry differs from scatterometry or reflectometry by the fact that it does not only measure reflected light intensity of both p- polarization and s-polarization states but also the relative phase differences of the p-state with respect to the s-state expressed in Delta, resulting in general elliptically polarized light:

Δ=arg(Rₚ−Rₛ) (2)

Micro-ellipsometry tries to extract these both quantities for all angles of incidence and also for all azimuth (0 . . . 360 degrees) with respect to the measured target structures.

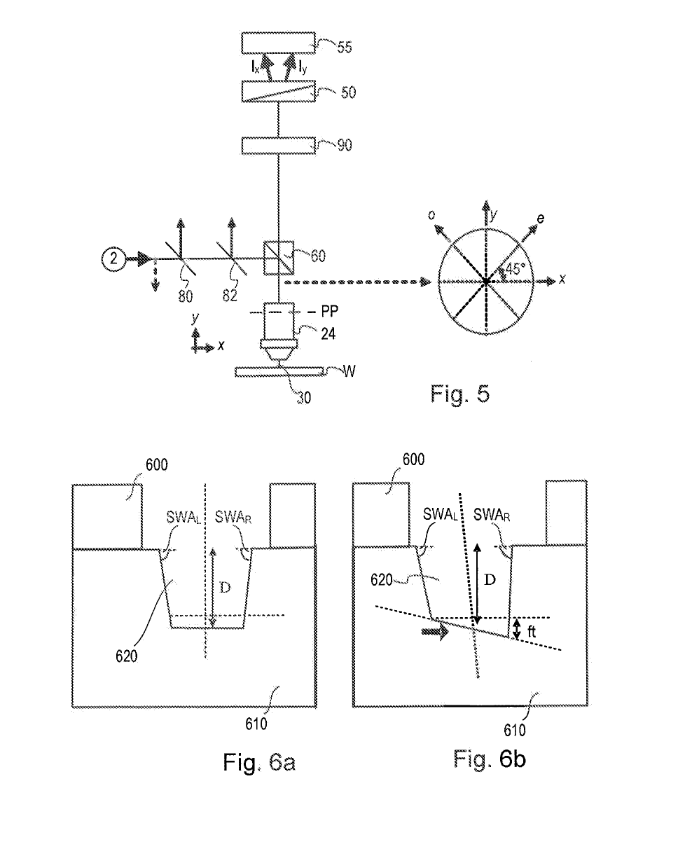

FIG. 5 shows an example of an ellipsometric sensor (or an ellipsometer) which may be used to determine the shapes and other properties of structures on a substrate. Illumination radiation from source P is reflected from a structure 30 on a target portion of a substrate W and, on its return journey from the substrate, is linearly polarized along one of the two eigen-polarizations of three beamsplitters that are present in the sensor (the eigen-polarizations being measured with respect to the x or y direction as shown in FIG. 5). A first beamsplitter 60 reflects part of the illumination to two further beamsplitters: one beamsplitter 80 sends part of the illumination to an imaging branch; and another beamsplitter 82 sends part of the illumination to a focus branch. The first beamsplitter 60 is a non-polarizing beamsplitter that directs the rest of the beam to a camera CCD. Having passed through the non-polarizing beamsplitter 60, the polarized beam passes through a phase modulator 90 whose ordinary and extraordinary axes have been positioned at 45° with respect to the x and y directions. Alternatively a half-wave plate (or similar device) can be usedwhich imparts a fixed phase shift (or retardation 6). For a given wavelength, the phase shift can be unknown. However, it should be in the region of 90 degrees and can be determined from data analysis of the complete pupil results.

Subsequently, the beam is divided into its respective x- and y- polarization orientations using a polarizing beamsplitter, for instance a Wollaston prism 50. Each divided beam is then incident on a camera 55. The relative intensities Iₓ, I_{y} of the polarized beams are used to determine the relative polarization orientations of the different parts of the beam. From the relative polarization orientations, the effect of the structure 30 on the beam as a whole can be determined.

Conventional scatterometer pupils can be obtained by summing the intensities of the polarized beams impinging on the CCD, so as to calculate their average intensity: Iₓ+I_{y}, while ellipsometer pupils can be obtained by calculating their difference: Iₓ-I_{y}

At the point that the beam is split and directed onto the camera 55, the beam is either a TM (transverse magnetic) polarized beam or a TE (transverse electric) polarized beam. The pupil plane PP of the microscope objective 24 is shown in FIG. 5. It is at this pupil plane PP that the microscope objective focuses the radiation that is reflected and scattered from the surface of the substrate W. It is the image that is created at this pupil plane PP that is subsequently recreated on the camera 55, using lenses or other optics such that the acquired image contains the largest amount of information possible (i.e., because there is no loss of sharpness or scattering of radiation outside of the aperture of the camera 55).

FIG. 5 also shows a phase modulator 90 positioned between the non-polarizing beamsplitter 60 and the beamsplitter 50 that separates the polarized beams prior to transmitting those polarized beams to the camera 55. An eo-coordinate system that is orientated along the extraordinary and ordinary axes of the phase modulator 90 is also shown in FIG. 5 as a circle. This shows a relative position of the extraordinary and the ordinary axes compared to the y and x axes of the system.

Light or radiation of a fixed wavelength from a source P with a known polarization state p is reflected from the target 30 on the surface of the substrate W to be investigated. For calibration purposes, the target 30 may be simply the plane surface of the substrate. The fixed-wavelength light or radiation reflects at multiple angles of incidence (for example θᵢ=0-80°) and at all azimuth angles (A=0-360°). Ranges within these ranges (or even outside of the listed range for the angle of incidence) may also be selected for calibration and other purposes, depending on the processing capacity available. The reflected light or radiation beam (as the incident light beam) consists of a full available range of light rays with different polarization states. The reflected light or radiation is received by a microscope objective 24 and focused on the pupil plane PP, which is reproduced at camera 55.

Up to now, such ellipsometry techniques have been used for direct measurement of structure attributes such as critical dimension CD and sidewall angle SWA. However, there has been no apparent reason to extend its use to measurement of overlay error; that is the undesired lateral shifts between layers of a structure.

In current overlay measurement practice the measured pupils are not compared to calculated results from reconstruction techniques such as rigorous coupled-wave analysis (RCWA), but instead asymmetries in the pupils are detected. This saves a lot of calculation effort and consequently increases speed.

Taking the example of a line of resist on top of a buried trench in silicon, pupils are measured for the case where the resist line has been deliberately shifted by a first amount (for example, 20 nm to the left) and also for the case where the resist line has the opposite shift (that is, in this example, 20 nm to the right). This is called the bias. The observed asymmetry in the resultant spectrometry pupils is the result of these biases, as well as actual overlay error. Conventional spectrometry pupils, based on average intensity are measured for both of these cases, I⁺ and I⁻. From these the asymmetry can be calculated by creating new pupils A⁺ and A⁻ such that: A⁺=I⁺−Rot180(I⁺) and A⁻=I⁻−Rot180(I⁻), where I⁺ is the spectrometry pupil in the first case with “overlay+bias” and Rot180(I⁻) is the rotation of this pupil through 180 degrees; and similarly I⁻ is the spectrometry pupil in the second case with “overlay-bias” and Rot180(I⁻) is the rotation of this pupil through 180 degrees. Therefore, for every distinct pixel out of the pupil an amount of asymmetry can be attributed to the actual overlay error by means of a simple formula:

Overlay=bias* (A⁺+A⁻)/(A⁺−A⁻) (3)

The total overlay error is the average of all the pixels.

This overlay determination relies on being able to determine the position of layers relative to each other. FIGS. 6a and 6b show a resist grating over a trench so as to illustrate the problems in doing this. Equation (3) assumes that the bottom-layer has an ideal shape and is in itself not asymmetric. This ideal situation is shown in FIG. 6a. Here it can be seen that the trench floor is horizontal, and left and right side wall angles SWA_{L} and SWA_{R} are equal.

However when plasma etching techniques are used, the resultant trenches tend to show asymmetry in side wall angles (SWA_{L} and SWA_{R} are not equal) as well as a skew in the bottom of the etched trench, or floortilt (ft). FIG. 6b shows such a trench. The conventional overlay determination method described above proves to be seriously affected by this asymmetry in the shape of the trench.

The inventors have determined that this sensitivity to shape parameters of the bottom layer trench can be largely reduced by using ellipsometrical pupils. Accordingly, A⁺ and A⁻ can be constructed and overlay calculated according to equation (3) using ellipsometrical pupils with plus-bias I⁻=(Iₓ−I_{y})⁺ and with minus-bias I⁻=(Iₓ−I_{y})⁻ in place of the conventional scatterometry pupils with plus-bias 1⁺=(Iₓ+I_{y})⁺ and with minus-bias I⁻=(Iₓ+I_{y})^{'1}.

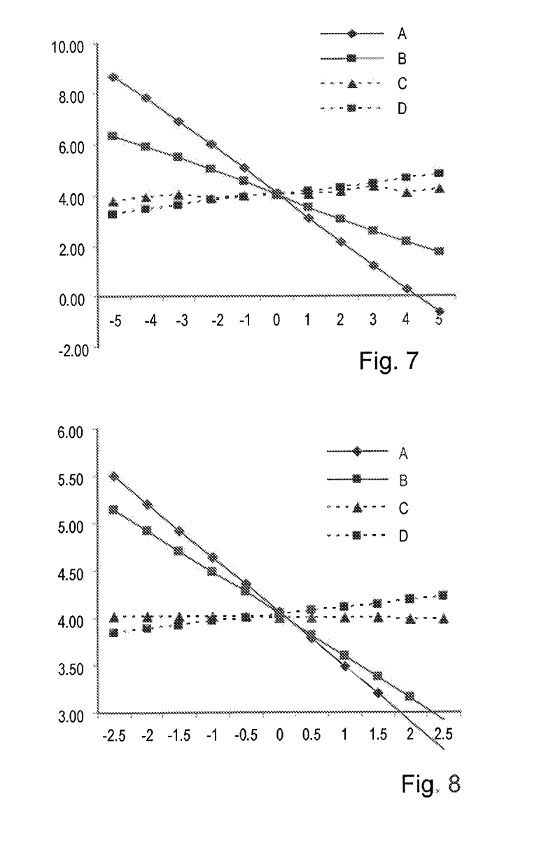

FIG. 7 plots the measured overlay on the y-axis against the degree of floortilt on the x-axis for a single structure. In this example CD=250 nm, pitch=500 nm and a regular wavelength of 600 nm is chosen with a trench depth of 50 nm and a resist thickness of 50 nm. FIG. 8 plots the measured overlay on the y-axis against the degree of SWA asymmetry on the x-axis for the same structure. In both plots, lines A and B relate conventional scaterometry pupils (TM and TE respectively) and lines C and D relate ellipsometry pupils (TM and TE respectively). It can be seen from FIG. 7 that conventional scatterometry pupils show a significant dependence between the measured overlay and the tilt in the trench floor (as much as a nanometer undesired shift for every nanometre floortilt). This is largely reduced to zero when the ellipsometer pupils are used. It can also be seen from FIG. 8 that there is a similar dependence between measured overlay and SWA asymmetry. Again, this effect is largely reduced to zero using the ellipsometer pupils.

The inventors have also discovered that a small amount of transparent material such as a bottom anti-reflective coating (Barc) between the top silicon and the bottom resist can improve this non-dependence of measured overlay on trench asymmetry yet further.

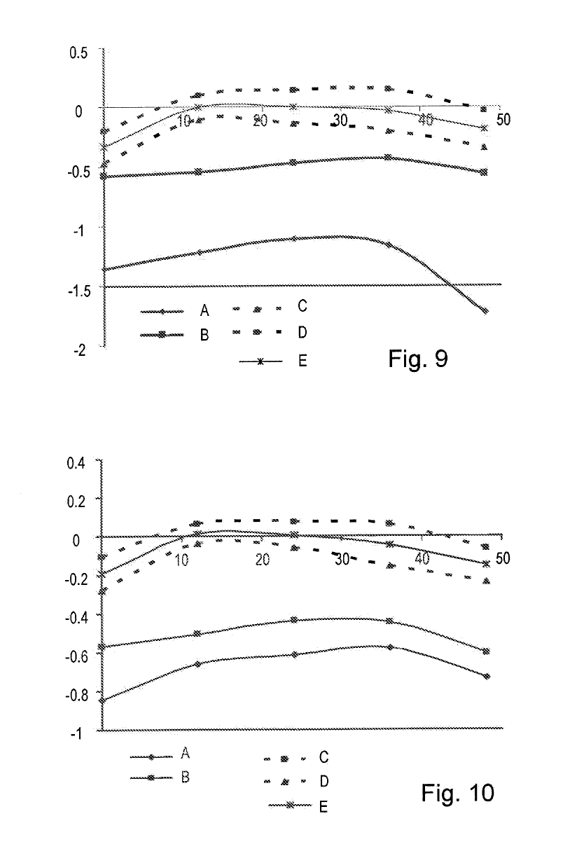

FIGS. 9 and 10 illustrate that effect of the Barc layer on overlay measurement with respect to floortilt and SWA asymmetry respectively. In both plots, lines A and B relate to conventional scaterometry pupils (TM and TE respectively), lines C and D relate to ellipsometry pupils (TM and TE respectively) and line E represents the average of the overlay errors of lines C and D. It can be seen in both cases that the presence of Barc-layers between 10 nm and 40 nm makes the ellipsometry pupils almost immune to trench asymmetry. In practical there exists an optimal measurement wavelength where this immunity is most pronounced, i.e., the wavelength can be tuned to obtain maximal immunity.

The targets used by conventional scatterometers are relatively large, e.g., 40 μm by 40 μm, gratings and the measurement beam generates a spot that is smaller than the grating (i.e., the grating is underfilled). This simplifies mathematical reconstruction of the target as it can be regarded as infinite. However, in order to reduce the size of the targets, e.g., to 10 μm by 10 μm or less, e.g., so they can be positioned in amongst product features, rather than in the scribe lane, so-called “small target” metrology has been proposed, in which the grating is made smaller than the measurement spot (i.e., the grating is overfilled). Placing the target in amongst the product features increases accuracy of measurement because the smaller target is affected by process variations in a more similar way to the product features and because less interpolation may be needed to determine the effect of a process variation at the actual feature site. Typically small targets are measured using dark field scatterometry in which the zeroth order of diffraction (corresponding to a specular reflection) is blocked, and only higher orders processed. Examples of dark field metrology can be found in international patent applications WO 2009/078708 and WO 2009/106279 which documents are hereby incorporated by reference in their entirety. In some techniques, for example, multiple pairs of differently biased gratings are required for accurate determination for overlay. The use of multiple pairs of gratings also increases the space on the substrate that needs to be devoted to metrology targets and hence is unavailable for product features. Even where targets are placed within scribe lanes, space is always at a premium. It will always be desired to shrink the targets.

It is proposed to extend the overlay measurement using ellipsometry methods disclosed herein to dark field measurement techniques, so that targets can be made smaller than in the above embodiments.

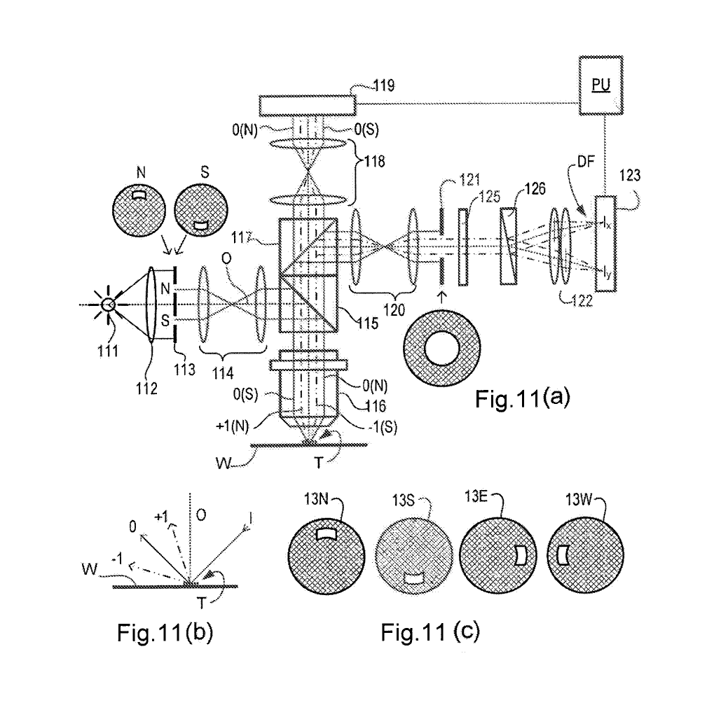

A dark field metrology apparatus according to an embodiment of the invention is shown in FIG. 11(a). This is largely similar to previously disclosed dark field metrology apparatus, with the exception to the second measurement branch, which will be described below. A target grating T and diffracted rays are illustrated in more detail in FIG. 11(b). The dark field metrology apparatus may be a stand-alone device or incorporated in either the lithographic apparatus LA, e.g., at the measurement station, or the lithographic cell LC. An optical axis, which has several branches throughout the apparatus, is represented by a dotted line O. In this apparatus, light emitted by source 111 (e.g., a xenon lamp) is directed onto substrate W via a beam splitter 115 by an optical system comprising lenses 112, 114 and objective lens 116. These lenses are arranged in a double sequence of a 4F arrangement. Therefore, the angular range at which the radiation is incident on the substrate can be selected by defining a spatial intensity distribution in a plane that presents the spatial spectrum of the substrate plane, here referred to as a (conjugate) pupil plane. In particular, this can be done by inserting an aperture plate 113 of suitable form between lenses 112 and 114, in a plane which is a back-projected image of the objective lens pupil plane. The rest of the pupil plane is desirably dark as any unnecessary light outside the desired illumination mode will interfere with the desired measurement signals.

As shown in FIG. 11(b), target grating T is placed with substrate W normal to the optical axis O of objective lens 116. A ray of illumination I impinging on grating T from an angle off the axis O gives rise to a zeroth order ray (solid line O) and two first order rays (dot-chain line +1 and double dot-chain line −1). However, the two first order rays are shown for illustration only and it should be appreciated that to measure overlay (from asymmetry), only one such first order ray is used at one time. It should also be remembered that with an overfilled small target grating, these rays are just one of many parallel rays covering the area of the substrate including metrology target grating T and other features. Since any aperture in plate 113 has a finite width (necessary to admit a useful quantity of light), the incident rays I will in fact occupy a range of angles, and the diffracted rays 0 and +1/−1 will be spread out somewhat. According to the point spread function of a small target, each order +1 and −1 will be further spread over a range of angles, not a single ideal ray as shown.

At least the zeroeth and first orders diffracted by the target on substrate W are collected by objective lens 116 and directed back through beam splitter 115. Returning to FIG. 11(a), this is illustrated by designating aperture plates with diametrically opposite apertures as north (N) and south (S) respectively. The +1 diffracted rays from the north aperture, which are labeled +1(N), enter the objective lens 116, and so do the −1 diffracted rays from the south aperture (labeled −1(S)).

A second beam splitter 117 divides the diffracted beams into two measurement branches. In a first measurement branch, optical system 118 forms a diffraction spectrum (pupil plane image) of the target on first sensor 119 (e.g., a CCD or CMOS sensor) using the zeroth and first order diffractive beams. Each diffraction order hits a different point on the sensor, so that image processing can compare and contrast orders. The pupil plane image captured by sensor 119 can be used for focusing the metrology apparatus and/or normalizing intensity measurements of the first order beam.

In the second measurement branch, an aperture stop 121 is provided in a plane that is conjugate to the pupil-plane. Aperture stop 121 functions to block the zeroth order diffracted beam so that the image of the target formed on sensor 123 is formed only from the first order beam. This is the so-called dark field image, equivalent to dark field microscopy. Optical system 120, 122, polarizing (Wollaston) prism 126 and half-wave plate (or phase shifter) 125 forms two images Iₓ and I_{y}, of the target T on sensor 123 (e.g., a CCD or CMOS sensor). This measurement branch is therefore largely similar to the measurement apparatus of FIG. 5, except real images of the target are sensed on sensor 123, using only the first order light.

The images captured by sensors 119 and 123 are output to image processor and controller PU, the function of which will depend on the particular type of measurements being performed. As before, for conventional dark field overlay measurement the integrated intensities Iₓ and I_{y} can be summed, while for ellipsometrical dark field overlay measurements, these two intensities are subtracted: Iₓ−I_{y}.

FIG. 3(c) shows a set of aperture plates 13N, 13S, 13E, 13W which can be used to make asymmetry measurements of small target gratings, for at least some embodiments of the present invention. Using aperture plate 13N, for example, illumination is from north only, and only the +1 order will pass through field stop 121 to be imaged on sensor 123. By exchanging the aperture plate for plate 13S, then the −1 order can be imaged separately, allowing asymmetries in the target grating T to be detected and analyzed. The same principle applies for measurement of an orthogonal grating and illuminating from east and west using the aperture plates 13E and 13W. The aperture plates 13N to 13W can be separately formed and interchanged, or they may be a single aperture plate which can be rotated by 90, 180 or 270 degrees. As mentioned already, the off-axis apertures illustrated in FIG. 3(c) could be provided in field stop 121 instead of in illumination aperture plate 13. In that case, the illumination could be on axis. The aperture plate 113 and field stop 121 may take different forms depending on the particular embodiment, for example aperture plates which only allow half-orders to pass are described, as well as those with apertures at intermediate positions to those described (e.g., northeast).

In order to make the illumination adaptable to these different types of measurement, the aperture plate 113 may contain a number of aperture patterns on a disc which rotates to bring a desired pattern into place. Alternatively or in addition, a set of plates 113 could be provided and swapped, to achieve the same effect. A programmable illumination device such as a deformable mirror array can be used also. As just explained in relation to aperture plate 113, the selection of diffraction orders for imaging can be achieved by altering the field stop 121, or by substituting a field stop having a different pattern, or by replacing the fixed field stop with a programmable spatial light modulator. While the optical system used for imaging in the present examples has a wide entrance pupil which is restricted by the field stop 121, in other embodiments or applications the entrance pupil size of the imaging system itself may be small enough to restrict to the desired order, and thus serve also as the field stop.

While the illumination system shown is an off-axis illumination mode, in another embodiment of the invention, on-axis illumination of the targets is used and an aperture stop with an off-axis aperture is used to pass substantially only one first order of diffracted light to the sensor. In yet other embodiments, 2nd, 3rd and higher order beams (not shown in FIG. 11) can be used in measurements, instead of or in addition to the first order beams.

Three different embodiments will now be described, in which the position of optical active elements, orientation of grating with overlay, and/or polarization direction of the input light are varied.

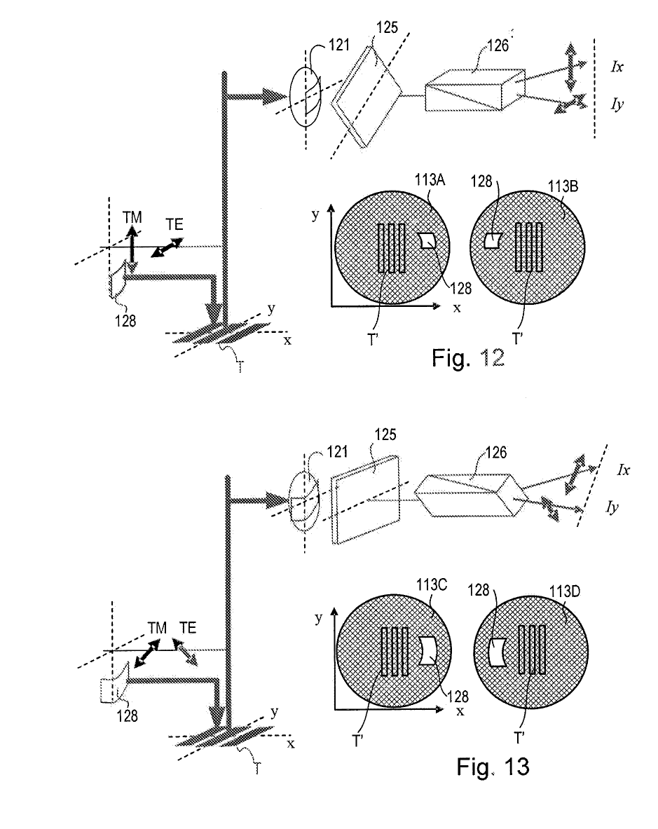

FIG. 12 shows a first of these embodiments, showing only the relevant features of the apparatus of FIG. 11, using the same labels. The target T under test is oriented parallel to the y-axis and the illumination beam is TM or TE polarized. Since the ellipsometer pupils have a particular symmetry where quadrants 1 and 3 have opposed sign to quadrants 2 and 4, it is important to obtain the integrated intensities Iₓ or I_{y} from a single quadrant only. Therefore the target T is illuminated with only a half-order via aperture 128, using aperture plates 113A (−half-order) and 113B (+half-order). Each depiction of the aperture plates 113A-113F in these embodiments also shows a representation of the target T′, so as to show the relative orientation of aperture 128 and target T. The diffracted half-order pupil is projected through the order filter 121 removing remnant zero order reflections. At this position the intensities in x and y directions are still pupil based so these intensities are linked to angles of incidence and azimuth values. This filtered half-order pupil then enters the ellipsometer branch consisting of a quarter wave plate 125 positioned under 45 degrees orientation and a polarizing prism 126 which separates the two polarization directions Iₓ and I_{y}.

A main problem with ellipsometer pupils is that the highest sensitivity to grating parameters are found around the pupil diagonals whereas conventional scatterometry is most sensitive around the x- and y-axis. This is discussed further in the applicant's co-pending application U.S. appl. Ser. No. 13/033,135, incorporated by reference herein in its entirety.

The fact that only half-orders are used in this embodiment means that half of the available amount of light is removed by the half-order apertures. In order to obtain full advantage of the largest possible amount of diffracted light from the target it is preferable to use a full order.

FIG. 13 shows one variation on the FIG. 12 arrangement to address these issues. In this embodiment, the ellipsometer branch, consisting of quarter waveplate 125 and polarizing prism 126, is rotated by 45 degrees. This means that the source polarization should have an orientation of +45 or −45 degrees with respect to the machine x- and y-axis. Aperture plates 113C and 113D now have apertures 128 which transmit all the first order light

As well as using all the available first order light, a further advantage of this embodiment is that the grating can still be oriented parallel to the y-axis.

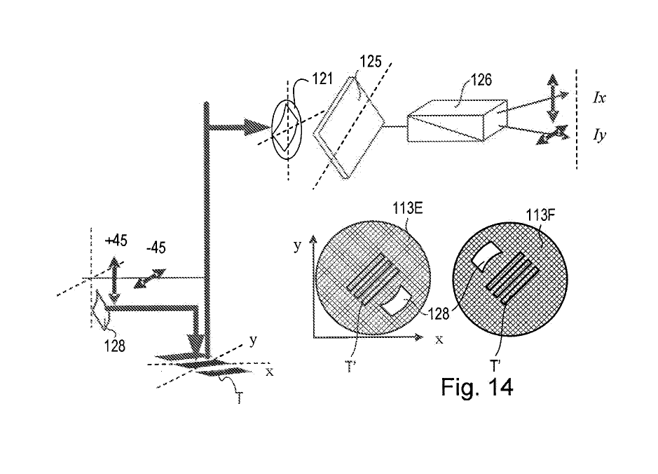

FIG. 14 shows another variation on the FIG. 12 arrangement that, like the FIG. 13 embodiment, allows full orders to be used. In this embodiment, the source light is TM or TE polarized, the quarter wave plate 125 is positioned at 45 degrees orientation and the polarizing prism 126 is parallel to the machine axes. In this respect the arrangement is similar to that of FIG. 12. In order to maximize the use of the positions around the diagonals of the ellipsometry pupil, the target T is rotated through 45 degrees under the objective lens. Also this target T is illuminated (A) with 45 degrees azimuth for both the +1 and −1 orders, using aperture plates 113E and 113F.

An advantage of the FIG. 14 arrangement over that of FIG. 13 is that the source polarization is normally orientated while full orders of light can be used. This is important because non-polarizing beamsplitters are never completely non-polarizing. With light at 45 degrees, the beamsplitter's mirror surfaces can never be made such that reflection is 50% and phaseshift after reflection is zero degrees. If light enters the beamsplitter with a 1:1 mix of TE and TM radiation (that is linearly polarized at 45 degrees) and these components combine after reflection, the beam becomes elliptical.

Using an illumination source with strictly linear polarization means that, after reflection, these beams remain linear polarized. The resultant disadvantage is that the target needs to be rotated through 45 degrees.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g., semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. An inspection method comprising:
reflecting a radiation beam with a known polarization off a periodic structure on a substrate, the periodic structure having been formed by a lithographic process;
splitting the reflected radiation beam into first and second orthogonally polarized sub-beams;
shifting the phase of the first sub-beams with respect to the second sub-beam;
substantially simultaneously detecting a first image resultant from the first sub-beam and a second image resultant from the second sub-beam;
using a difference in intensity values derived from the detected first and second images together to determine an overlay error in the periodic structure.

2. The method of claim 1, wherein the at least one periodic structure has been formed with a predetermined alignment bias between successive layers in addition to the overlay error, and images are determined for at least two of the periodic structures, each having a predetermined alignment bias that is equal in magnitude but opposite in direction to the other.

3. The method of claim 2, wherein the overlay error is determined by measuring the asymmetry in the images determined from the periodic structures.

4. The method of claim 1, wherein the images are pupil plane images.

5. The method of claim 1, wherein the images are image-plane images.

6. The method of claim 1, wherein:
the first image is formed using a first part of non-zero order diffracted radiation while excluding zero order diffracted radiation; and
the second image is formed using a second part of the non-zero order diffracted radiation which is symmetrically opposite to the first part, in a diffraction spectrum of the periodic structure.

7. The method of claim 6, wherein the two images are obtained from the same structure, the structure comprising the at least two periodic structures.

8. The method of claim 6, wherein the first and second parts of the non-zero order diffracted radiation comprise only half-orders.

9. The method of claim 1, wherein the periodic structure and the initial linear polarization of the radiation beam are angled non-orthogonally relative to each other during the reflecting.

10. The method of claim 9, wherein the angle between the periodic structure and the initial linear polarization of the radiation beam is in the region of 45 degrees.

11. The method of claim 1, wherein the phase is shifted by a phase modulator, the phase modulator providing a known phase shift.

12. The method of claim 1, wherein the phase is shifted by a quarter-wave plate.

13. The method of claim 1, wherein the reflecting step comprises reflecting the radiation beam off a structure at a range of incident and azimuth angles.

14. The method of claim 1, wherein the wavelength of the radiation beam is selected to so as to provide greatest independence of the overlay determination to asymmetry in the structure.

15. The method of claim 1, comprising an initial step of using a lithographic process to form the periodic structure on the substrate.

16. The method of claim 1, comprising forming at least one intermediate layer between an etched first layer and a subsequent layer.

17. The method of claim 16, wherein the intermediate layer is a substantially transparent layer.

18. The method of claim 17, wherein the transparent layer comprises a bottom anti-reflective coating.

19. The method of claim 16, wherein the at least one intermediate layer comprises a stack of layers of different materials.

20. The method of claim 16, wherein the intermediate layer is between about 5 nm and about 50 nm in thickness.

21. A computer readable medium comprising instruction code which, when run on computer equipment controlling an inspection or lithographic apparatus, causes the inspection apparatus to carry out an operations comprising:
reflecting a radiation beam with a known polarization off a periodic structure on a substrate, the periodic structure having been formed by a lithographic process;
splitting the reflected radiation beam into first and second orthogonally polarized sub-beams;
shifting the phase of the first sub-beams with respect to the second sub-beam;
substantially simultaneously detecting a first image resultant from the first sub-beam and a second image resultant from the second sub-beam; and
using a difference in intensity values derived from the detected first and second images together to determine an overlay error in the periodic structure.
